(19) United States
(12) Patent Application Publication
(10) Pub. No.: US 2005/0031055 A1
(43) Pub. Date: Feb. 10, 2005

(54) Bit slicer system and method for synchronizing data streams

(75) Inventor: James W. Ernst, Carmel, IN (US)

Correspondence Address: Doreen J. Gridley;ICE MILLER, One American Square, Box 82001, Indianapolis, IN, 46282-0002, US

(73) Assignee: INDesign, LLC, (an Indiana limited liability company), Indianapolis, IN (US)

(21) Appl. No.: 10/910,749

(22) Filed: Aug. 3, 2004

Related U.S. Application Data
(60) Provisional application No. 60/492,709, filed on Aug. 5, 2003.

(51) Int. Cl. H03D 1/00

(52) U.S. Cl. 375/342

(57) ABSTRACT

A bit slicer system is provided for synchronizing a data stream. The bit slicer system includes a processor that may include a shift register and a plurality of particle processors coupled to the shift register. Each particle processor may be configured to generate a voted majority for a plurality of binary samples. The processor may also include a bit function generator coupled to the plurality of particle processors that is configured to generate a score from the plurality of voted majorities. The processor may read binary samples from a data stream, shift the binary samples through the shift register, load subsets of the binary samples into the particle processors, load voted majorities generated by the particle processors into the bit function generator, and adjust the shift register based on the score generated by the bit function generator.

### BACKGROUND OF THE INVENTION

This non-provisional patent application is a continuation-in-part of U.S. provisional patent application Ser. No. 60/492,709, filed Aug. 5, 2003. The present invention relates to a system and method for synchronization, and, more particularly, to a system and method for synchronizing asynchronously transmitted data streams.

When sending digital data from a transmitting terminal to a receiving terminal, the data is sometimes sent asynchronously, or without a synchronizing clock signal. Asynchronous communications are used in a myriad of applications, including but not limited to the transmission of audio, video, and other data, and asynchronous communication occurs over wired and wireless media. Such wired and wireless media include, but are not limited to: wires (twisted pair, coaxial cable, universal serial bus (USB), Firewire®, Ethernet®, etc.), fiber optics, radio frequency (RF) waves, infrared (1R) waves, and satellite transmissions. Irrespective of the application or transmission media, when the data arrives at the receiving terminal, the data must be processed and analyzed so that it becomes synchronized with the transmitting terminal.

The synchronization of asynchronous data can be accomplished in one of several ways known in the art. Today, there are two widely-used processes for synchronizing asynchronous data streams. One such process uses a “start bit”, a “synchronizing bit”, or a bit pattern at the beginning of a data stream. The “start bit”, “synchronizing bit”, or bit pattern not only serves as an indicator of the beginning of the data stream, but also provides a starting point for sampling of each bit. The other widely-used process utilizes transitions (timing of edges) in the data stream and calculates the best sampling location from these transitions.

These prior art methods may have several shortcomings. For the method using a start bit or the like, issues can arise during transmission in the event the start bit is not detected or is corrupted during transmission. Further, the requirement for an additional bit or bit pattern results in the transmission of bits other than the data stream, such that the transmitter may have to create such bit or bits, which can introduce inefficiencies in the process of transmission. As to the use of transitions, noise has been known to corrupt such timing, which may result in difficulties during the synchronization of the data.

The two prior art methods discussed above synchronize a digital bit stream, for example, such as the bit stream received by an asynchronous modem. There exist prior art methods that decode a digital signal modulated onto an analog carrier wave using an analog comparator. In these systems, the analog comparator determines voltage levels of the received carrier wave and calculates differentials and/or integrals of the analog signal to determine binary transitions (decode the signal).

One such digital signal decoder is disclosed in U.S. Pat. No. 5,671,256 issued to Clark et al. on 23 Sep. 1997. Although prior art methods such as that disclosed by Clark et al. may refer to the analog comparator and related circuitry as a “bit slicer,” it should be recognized that this “bit slicer” is an analog bit slicer. The purpose of the prior art analog bit slicers is to decode an analog signal to recover a modulating digital signal.

Another issue that may arise in data stream synchronization is that of latency (delay). In ideal circumstances, data would be transmitted instantaneously between the transmitting terminal and the receiving terminal. However, several factors can contribute to latency. These factors include propagation delay (the time it takes for a data packet to travel through a medium), transmission time (the time it takes for a transmitter to send a packet of data), router and related processing delays, and other processor delays. Consider, for example, that in transmission of streaming audio data using RF as the means of transmission, there are necessarily delays in causing the data to leave to the transmitter, be transmitted through the air on the RF waves, received at the receiver, converted from analog to digital (if the data is modulated onto an RF carrier wave), and subsequently processed (such as to eliminate white noise or perform some other error correction or signal enhancement).

The prior art methods used for synchronization of asynchronously transmitted data may also contribute to latency. Often, the synchronization analysis is performed by a processor after conversion of the data from analog to digital, and such processing generally results in latency. It is therefore desired to provide a system and method for synchronizing asynchronously transmitted data streams that do not possess the foregoing shortcomings. The system and method should effectively synchronize asynchronously transmitted data streams, even in the presence of noise, and without requiring that additional synchronizing data be transmitted with the data stream. It is further desired that the system and method have insignificant latency, particularly when compared to prior art synchronization systems and methods.

### SUMMARY

A bit slicer system is provided for synchronizing a data stream. The bit slicer system includes a processor that may include a shift register and a plurality of particle processors coupled to the shift register. Each particle processor may be configured to generate a voted majority for a plurality of binary samples. The processor may also include a bit function generator coupled to the plurality of particle processors that is configured to generate a score from the plurality of voted majorities. The processor may read binary samples from a data stream, shift the binary samples through the shift register, load subsets of the binary samples into the particle processors, load voted majorities generated by the particle processors into the bit function generator, and adjust the shift register based on the score generated by the bit function generator.

A method for synchronizing a data stream is also provided. The method includes storing a set of patterns and an associated score for each pattern in a memory. The method also includes sampling a binary data stream periodically to generate a plurality of samples, and loading each sample into a shift register. The method may include calculating binary particle values for a groups of the samples, wherein each binary particle value is the voted majority for the respective group of samples. The method may also include matching the binary particle values a to pattern of the set of patterns, and adjusting the shift register as a function of the score associated with the matched pattern of the set.

The system and method provided herein synchronize a digital signal, irrespective of whether the digital signal was previously modulated. The system and method are not dependent solely upon detection of a start bit or a start bit pattern, and can be utilized in the presence of noise or other data corruption. Additionally, the system and method may introduce considerably less latency than prior art systems and methods for the synchronization of digital signals.

### BRIEF DESCRIPTION OF THE DRAWINGS

FIG. 1 shows a block diagram of an illustrative bit slicer system.

FIG. 2 shows a diagrammatic illustration of the four levels of data manipulation used by one embodiment of the bit slicer system of FIG. 1.

FIG. 3 shows a diagrammatic illustration of various pattern scores used by one embodiment of the bit slicer system of FIG. 1.

FIG. 4 shows a diagrammatic illustration of scoring regions used by an embodiment of the bit slicer system of FIG. 1.

FIG. 5 shows a table of exemplary bit patterns, together with their respective particles, bits, and scores, as used by an embodiment of the bit slicer system of FIG. 1.

FIG. 6 shows a table of the scoring of an illustrative data stream as a bit pattern is convolved through a shift register of the bit slicer system of FIG. 1.

### DETAILED DESCRIPTION OF THE PRESENTLY PREFERRED EMBODIMENT

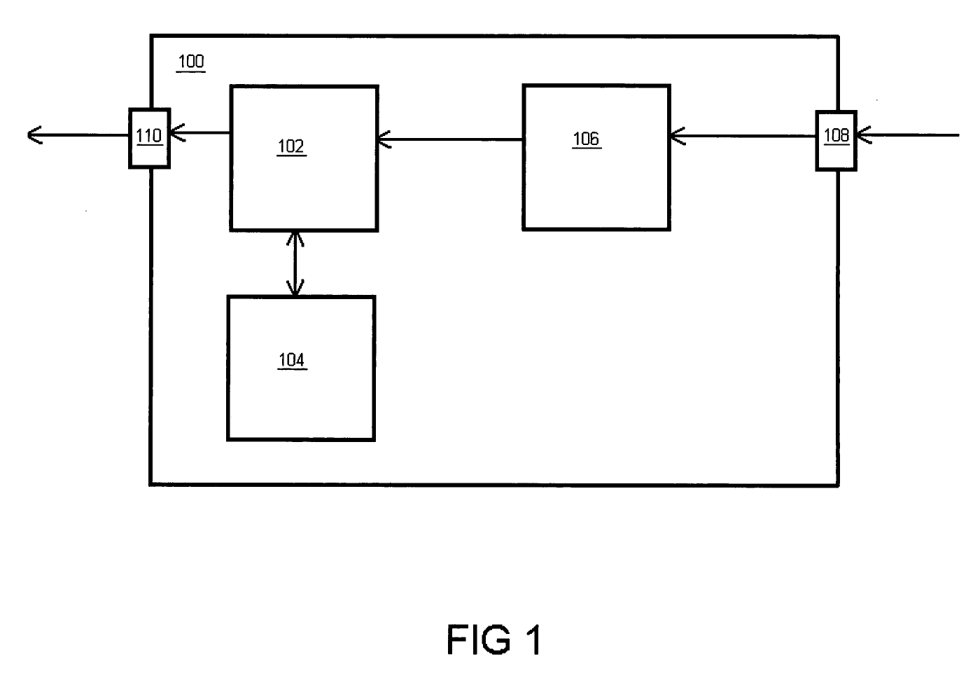

Turning to FIG. 1, a preferred embodiment of a bit slicer system 100 is shown. The bit slicer system 100 implements a method for synchronizing data streams, as described in greater detail below. The bit slicer system 100 comprises a processor 102 coupled to a memory 104. The processor is also coupled between an input 108 and an output 110. The bit slicer system 100 may also include an asynchronous data receiver 106 coupled between the input 108 and the processor 102. Alternatively, the bit slicer system 100 may receive asynchronous data at the input 108 from an external source. The processor 102 may be a microprocessor, a microcontroller, a gate array, or any other device capable of receiving a binary input and generating a binary output as a function of the input and a control algorithm.

In one embodiment, the processor 102 is a field programmable gate array (“FPGA”), such as the Spartan 2E FPGA available from Xilinx of San Jose, Calif., USA. The memory 104 may be a non-volatile memory that is separate from or integrated with the processor 102. In one embodiment, the memory 104 is an erasable programmable read-only memory (“EPROM”), such as the XC18V01 available from Xilinx. For example, the memory 104 may store code representing the control algorithm, and the processor 102 may load the code during a power-up. In another embodiment, the entire bit slicer system 100 is implemented with an FPGA. In another embodiment, processor 102 and memory 104 comprise an ASIC.

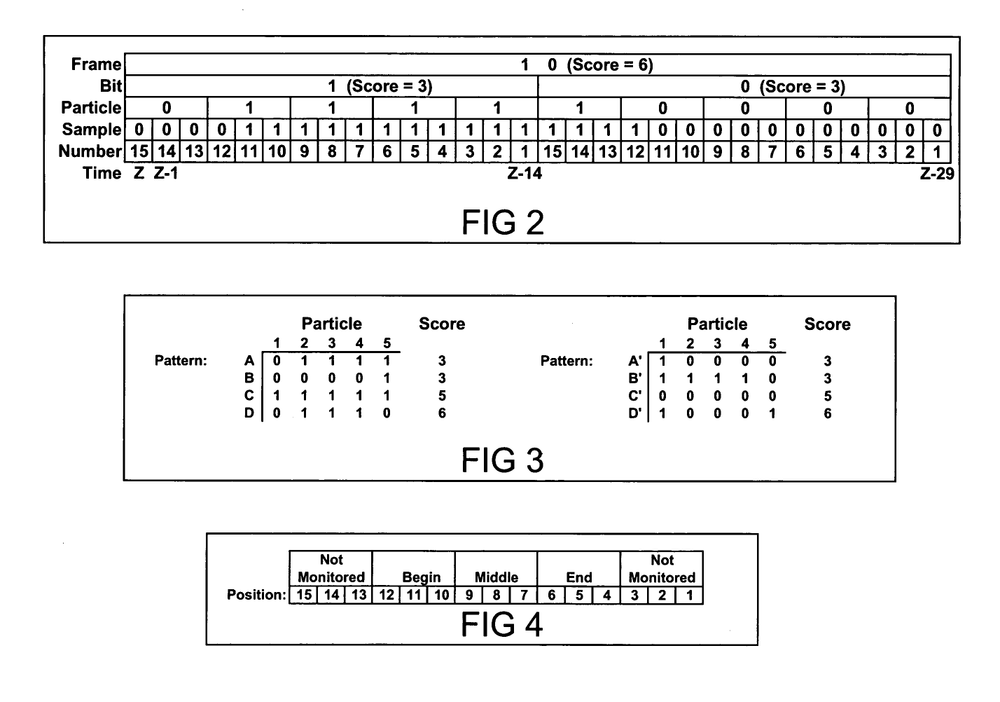

The bit slicer system 100 may use four levels of data manipulation for the purpose of synchronization. Each of these four levels is defined as follows, starting with the lowest level. FIG. 2 shows those levels diagrammatically. First, a “Sample” as used herein is the data present at the input 108 at a given time. In one embodiment, each bit of the input data is broken down into 15 samples. Each sample is effectively held in a shift register (see FIG. 5). At each point in time when a sample is taken, all of the samples are shifted and the new sample is added.

A “particle” as used herein is the voted majority of a set of contiguous samples. In one embodiment, there are three contiguous samples per particle, and five particles per bit (thus, 15 samples per bit). A “bit” as used herein is a set of contiguous particles. In one embodiment, a bit is five contiguous particles, which is also seen as 15 samples. Each bit has a score that is determined by the pattern of the bit's five particles, as explained in further detail below. A “frame” is a set of contiguous bits. A frame could be from one to any number of bits long. Each frame has a score that is determined by summing the scores of its bits as is described in further detail below. The size of the frame can be dynamically sized to conform to the mode of operation of the bit slicer system 100.

Each of these levels of data manipulation is represented in the example of FIG. 2. FIG. 2 shows a diagrammatic illustration of the four levels of data manipulation used by one embodiment of the bit slicer system 100. In this embodiment, each input bit comprises 15 samples, each particle comprises three samples, each bit comprises five particles, and each frame comprises 2 bits.

At this point it should be noted that the particle level of data manipulation is not necessary for proper operation of the bit slicer system 100. With a larger system and a larger scoring algorithm, each sample could be scored directly, without being voted upon and condensed into particles. With current technology, however, architectures without a particle level may create a scoring algorithm that is large, cumbersome, and thus slower. The particle level in this embodiment is used to preserve all of the granularity of each sample, yet condense the samples into a smaller representation of a bit in order to reduce the number of patterns that must be matched and scored at the bit level.

Another aspect of the bit slicer system 100 is the manner in which a score for a bit is created. As a data stream is shifted through the bounds of a bit (sample 15 through sample 1), the sample is scored as to how the pattern of the particles correlates to the pattern of the particles for a bit that is correctly centered. FIG. 3 shows a diagrammatic illustration of various pattern scores used by one embodiment of the bit slicer system 100, and, more specifically, the embodiment of FIG. 2. The eight patterns that obtain a score according to this embodiment are shown in FIG. 3. Note that the inverse of a (shown as patterns A′, B′, C′ and D′) pattern is scored the same as the pattern itself. An explanation of the patterns is as follows. Patterns A and A′ represent an almost perfect match of a centered bit, except that the bit boundary (edge) on the left is intruding by one particle. It is possible that this pattern results where a bit has not yet centered itself. In the embodiment of FIG. 3, Patterns A and A′ are weighted with a score of 3.

Patterns B and B′ are also represent an almost perfect match of a centered bit, but, unlike Patterns A and A′ where the bit boundary on the left is intruding, in Patterns B and B′ the bit boundary (edge) on the right is intruding by one particle. It is possible that this pattern also results where a bit has not yet centered itself. Thus, the score for Patterns B and B′ is the same as the score for Patterns A and A′. In the embodiment of FIG. 3, Patterns B and B′ are weighted with a score of 3. Patterns C and C′ are either an exact match of a centered bit, or a bit having boundaries (edges) that intrude upon the adjacent bits.

Patterns C and C′, in the embodiment of FIG. 3, are weighted with a score of 5, more than that of Patterns A, A′, B, and B′, and less than that of Patterns D and D′. Patterns D and D′ represent a bit that has both edges intruded upon by adjacent bits. Patterns D and D′ are scored the highest by the embodiment of FIG. 3, because these patterns have the smallest window of opportunity to be scored. In this embodiment, Patterns D and D′ are weighted by a score of 6, which is twice that of Patterns A, A′, B, and B′. In the embodiment of FIG. 3, any other patterns found within the boundaries of a bit are regarded as either not centered or noise, and are thus given a score of zero.

The bit slicer system 100 is not restricted to making a decision as to the center of a bit by analyzing only one edge or one bit, but may also analyze several bits and bit patterns simultaneously to determine the center of a single bit. The asynchronous data receiver 106 or the memory 104 may include a shift register (not shown) that takes in each sample. The shift register can be perceived to operate as a very large, single bit memory array. The larger the shift register, the more samples can be stored, and thus the more particles and bits can be attached to the shift register to create a larger frame. As the frame size grows, the summation of the bit values that represent the frame's score grow to include more bits, and thus the frame score represents the simultaneous score of more bits on a “per sample” basis, which creates a higher confidence in centering the data stream.

In one embodiment of the bit slicer system 100 as shown logically in FIG. 5, the system 100 comprises a 75-bit shift register 502 and, thus, can hold up to five bits in a frame. The 75-bit shift register 502 feeds 25 particle processors 504 (three samples per particle). Each of the particle processors 504 creates a separate 3:1 voted result. The 25 particle processors 504 then feed five bit function generators 506 (five particles per bit). Each bit function generator 506 generates a score for the respective generators' 506 own pattern of particles. A summer 510 calculates a frame score by simultaneously adding the five individual bit scores (maximum of five bits per frame) from the five function generators 506. The score of the entire frame of 75 samples is thus refreshed at every sample interval.

In one embodiment the bit slicer system 100 includes the capability of adjusting the shift register 502. The control of the bit slicer system 100 is set up so that the data that is taken from the data stream is centered at the point where the highest score of the frame appeared. The slicer has two modes: Preamble Mode and Normal Mode. In Preamble Mode, the bit slicer system 100 is allowed to adjust the shift register 502 quickly in order to find the middle of a bit. This efficiency is achieved because it is assumed the actual preamble will be constructed with the maximum number of edges, a continual “10” pattern, so that there are more edges for scoring. In Normal Mode, the bit slicer system 100 is considered locked onto a data stream and will adjust the shift register 502 more slowly. This reduction in adjustment speed is desirable because the bit slicer system 100 will be processing a synchronized stream after the preamble has been identified. Thus, any deviance from that position will be due to clock drift between the transmitter and the receiver. Such clock drift should be minimal.

From experiments performed in the laboratory with a raw bit slicer system's 100 scoring mechanism implemented according to the embodiment shown in FIG. 5, it was found that there was a definite peak in score at the middle of the bit and there were no false peaks at the transition points. With this information, it was understood that a score does not need to be monitored for the entire frame. Rather, the score only needs to be monitored around the perceived center of the bits in the frame.

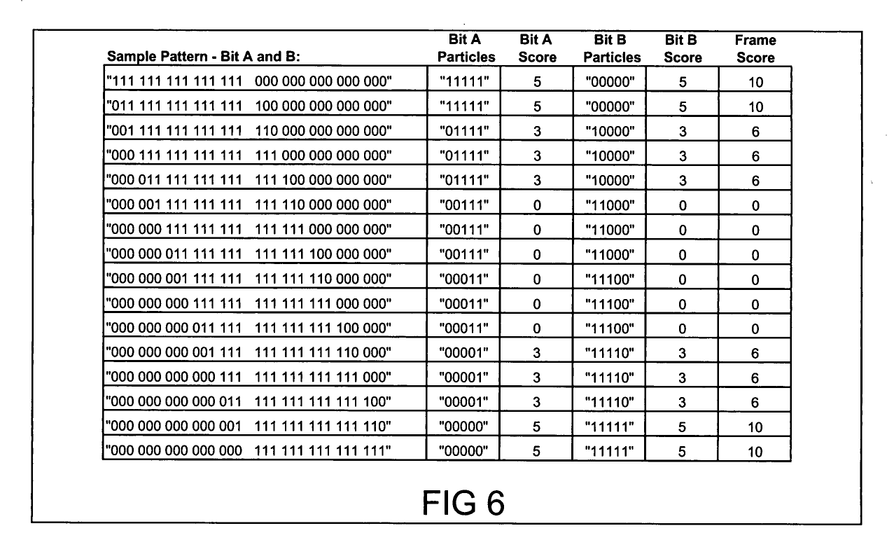

FIG. 6 shows a table of the scoring of an exemplary data stream as the bit pattern (15 sample per bit) “010” is convolved through the shift register 502. The pattern starts off at “10” and is shifted to “01”. The score for the frame shows that the highest score appears when the bit pattern is close to being centered. The data stream is at the center of the bit, plus or minus one sample.

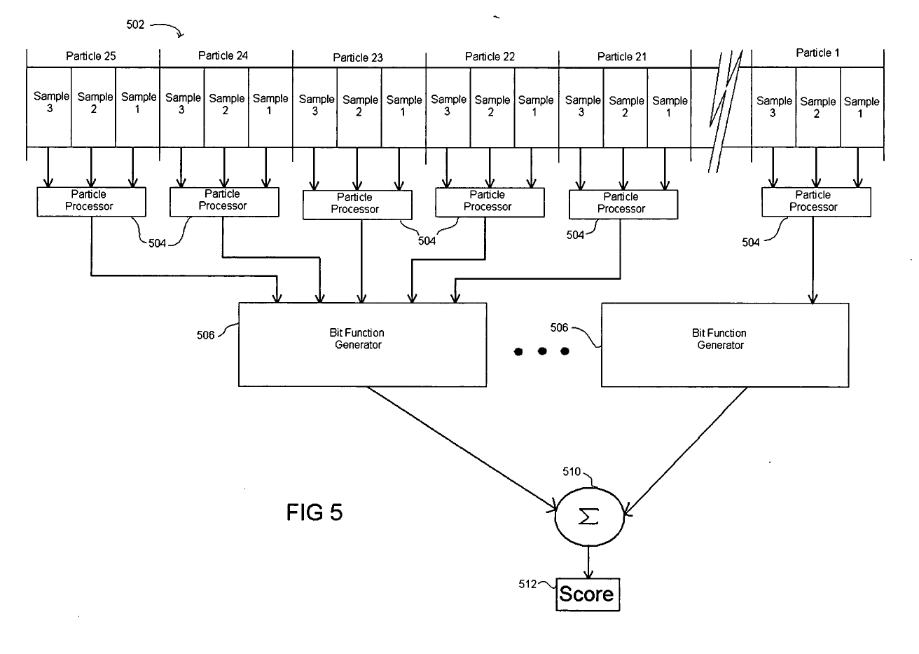

Of the 15 samples used for each bit, the bit slicer method described herein only monitors the frame score when the bit slicer system 100 is over what the bit slicer system 100 “perceives” to be the middle nine samples. As the convolution goes over each bit, this leaves three samples at the beginning and three samples at the end of each convolution where the frame score is not needed and thus not monitored. There are, therefore, three regions of three samples within the bit that are monitored: the beginning, the middle, and the end. The bit slicer system 100 records the high score and how many times it appeared in each region. The scoring regions for the embodiment comprising 15 samples shown in FIG. 4.

According to the bit slicer method described herein, if the high score appeared in the beginning region more than the middle region or the end region, then a command is given to shift left (subtract) a sample. If the high score appeared in the end region more than the middle region or beginning region, then a command is given to shift right (add) a sample. These commands go to a counter that keeps track of the command. The counter starts in the middle location. Each shift left command subtracts one from the counter, and each shift right command adds one to the counter. When the counter reaches its upper bound, a sample is added and the counter is reset. When the counter reaches its lower bound, a sample is subtracted and the counter is reset. In one embodiment, the counter for the bit slicer system 100 accumulates four commands before the counter is reset and the shift register is adjusted.

Because there is an option to subtract a sample in the bit slicer system 100, there are only two clock cycles from the last sample of the end region before the bit slicer system 100 must decide whether the bit slicer system 100 should make an adjustment. Thus, in two clock cycles (two samples), the bit slicer system 100 compares the high scores, decides whether the command counter needs to be adjusted, and then consults the command counter to decide if a sample should, in fact, be added or subtracted.

In one embodiment the bit slicer system 100 includes the capability to filter the data stream for both scoring and data extraction. When the data stream enters the bit slicer system 100, the data stream is copied into two streams—one copy for data extraction and one copy for scoring. The filter for the scoring of the frames may be created such that no spurious noise can deceive the bit slicer system 100 into interpreting data to be good data when the data actually is not good due to spurious noise.

In order not to confuse the bit slicer system 100 scoring, it is preferable to have no fewer than three identical particles in a row. In order to guarantee there would never be less than three identical particles in a row, the filter of the bit slicer system 100 can be devised to guarantee that there were no less than nine identical samples in a row. To accomplish this assurance, the filter for the scoring data of the bit slicer system 100 counts how many like samples there are in a row. Once nine are found, the scoring data output is changed to the value of the like samples. This filter using nine samples is referred to herein as a “high” filter.

The high filter works well for the scoring algorithms. However, in the presence of the high filter, over sixty percent (60%) of the bit may have to be present in order to register a bit. The requirement of over sixty percent (60%) is not desirable, however, as there are instances where only a small portion of the transmitted bit will make it to the receiver through the noise. The data stream was then created with a much more forgiving filter, referred to herein is a “light” filter. The data stream for data extraction, i.e., the light filter, only requires three like samples in a row in order to register a bit. Thus, with the light filter, only 20% of the bit is required to make it to the bit slicer in order for it to be registered.

The data stream is synchronized to the scoring stream so that when the scoring stream indicates it is at the best position to sample the bit, a corresponding sample is taken from the data stream. In testing of applications involving audio data streaming, the use of the high filter for scoring and the light filter for data extraction worked well. The rationale for having such a large filter on the scoring stream is that the scoring stream is only for scoring and centering the overall bit stream. If a bit is missed or overlooked in the scoring stream, it is acceptable, because that bit, if at least 20% if it was recovered contiguously, may still be sampled correctly in the data stream.

The particle level also provides for a degree of filtering. The filtering at the front end of the presently preferred embodiment is sufficient, however, so that filtering at the particle level is not necessary. However, if the filtering at the front end of the system were not present, this, or any arbitrary filtering function, could be provided at the particle level. In an extreme case, filtering could be provided as a function of the scoring algorithm. As an example, if the particle level were eliminated and the samples were scored directly (with 15 samples per bit) then the sample pattern “111111111111111” could have the same score as the pattern “111101111111011”, which effectively filters out the zeros at the fifth and thirteenth samples of the second pattern.

A synchronizing process is implemented by the bit slicer system 100 after the scoring process described hereinabove. In one embodiment, the synchronizing process comprises a process that has been used before in asynchronous communications. The synchronizing process uses a known pattern before the start of each data stream. When the bit slicer system 100 detects this pattern, the bit slicer system 100 understands that the detected pattern indicates the beginning of a data stream of a known length and starts shifting bits accordingly. Without this synchronization, there is no guarantee that the bits in the frame are in the right order, i.e., the bits in the frame may be shifted a few times in one direction.

In one embodiment of the bit slicer system 100, at startup the bit slicer system 100 puts itself in Preamble Mode and immediately starts looking for the preamble string. The preamble string is a series of “01” bits in order to produce the maximum number of edges for scoring, followed by a pattern of eleven bits. Once the eleven bit pattern is found, the bit slicer system 100 puts itself in Normal Mode and continues normal bit slicing operations.

For embodiments where the bit slicer system 100 is implemented wholly or partially with an FPGA, additional peripheral functions may be contained in FPGA. Such functions may have no direct relevance to the actual operation of bit slicer system 100 itself. These functions may have an inverse function that is implemented in the receiver. For example, if a transmitter uses Forward Error Correction and inserts Whitening, then the receiver must have an inverse function to remove the Whitening and decode the Forward Error Correction.

One additional peripheral function that the bit slicer system 100 may include is an Assembler function. An Assembler function takes advantage of the bit slicer system's 100 ability to produce a 4 or 5 bit data packet from a frame, and repackages the packets into 14 and 18 bit words. The repacking into words by such an Assembler function is useful for systems that have a data width of something other than the frame size of the bit slicer system 100. In this embodiment of the bit slicer system 100, the frame size can be dynamically adjusted between 4 and 5 bits. However, the system in which the bit slicer system 100 resides may have a data width of 14 or 18 bits. The assembler, therefore, can collect 4-bit and 5-bit frames from the bit slicer system 100 and assemble the frames into 14-bit or 18-bit words that may be used by the rest of the system.

Another additional peripheral function that the bit slicer system 100 may include is a Forward Error Correction function. A Forward Error Correction function appends parity information to a data word to allow the bit slicer to be able to detect and correct a single error in the word. Yet another additional peripheral function that the bit slicer system 100 may include is a Packaging function. A Packaging function takes a certain number of data words and groups them into a packet. The Packaging function is useful for the synchronization algorithm described herein.

Still another additional peripheral function that the bit slicer system 100 may include is a CRC Creation and Checking function. A CRC Creation and Checking function creates a 16-bit CRC from the data packet and appends it to the end of the packet to be checked at the receiver. The bit slicer system 100 may also include is a Whitening function. A Whitening function adds white Gaussian pseudorandom noise to the data stream and removes the noise at the receiver. The Whitening function is very useful for eliminating large strings of consecutive ones or zeros detected in the data stream. The bit slicer system 100 could also include is an Interleaving function. An Interleaving function interleaves the data. Interleaving of data is performed to alleviate the errors incurred by a burst of noise in the data stream. By interleaving data, if a burst of noise occurs, instead of such noise possibly wiping out an entire data word, a bit slicer system 100 embodiment that includes interleaving can spread the errors over many data words. This spreading of errors makes it more likely that the data can be recovered.

One embodiment of the bit slicer bit slicer system 100 includes Assembler, Forward Error Correction, Packaging, CRC Creation/Checking, and Whitening functions in a FPGA, or otherwise in the processor 102. It is envisioned that the Interleaving function could also be included, as well as any combination of these, or other well-known functions, to work with the bit slicer system 100.

It will be appreciated by those of skill in the art that the bit slicer system 100 examines the pattern of the edges in a data stream instead of the timing of the edges, as is done in many prior art systems. The process of bit slicer system 100 uses a mix of pattern matching and correlations. The bit slicer system 100 matches the patterns of what is considered a “centered bit” to the data stream. As to correlation, the bit slicer system 100 “scores” the pattern match to the data stream as the pattern match and data stream are convolved with each other. The result is that the bit slicer system 100 analyzes and locks a data stream into synchronization. The bit slicer system 100 creates no significant latency, and does not require the transmission of data in addition to the data stream to be received. The method implemented by the bit slicer system 100 is also efficient, and inexpensive.

It will also be appreciated that the bit slicer system 100 synchronizes a digital signal, irrespective of whether the digital signal was previously modulated. This feature is differentiated from prior art analog bit slicers that decode an analog signal to recover a modulating digital signal.

It will be further appreciated that the bit slicer system 100 may utilize alternatives to the embodiments discussed hereinabove and still be within the scope of the claims following this description. Other FPGAs or chips may be used for execution of the functions of the bit slicer system 100. It is possible that the number of bits in the sample, or in the particle may differ from the 15 sample bits and 5 particle bits set forth in the above discussion. However, it will also be appreciated that there may be issues associated with modifications to the 15 sample bit/5 particle bit scheme. For example, fewer samples may be insufficient for analysis. More samples may slow down the process, and therefore may require greater processing power and storage to avoid undesired latency introduced by the scoring process.

It will be further appreciated that the exact scores assigned to possible patterns may differ from that set forth herein. Such scores may be limited or bounded, however, by either their ratio to one another or by the desired outcome. If the ratio of scoring of different patterns are not weighted reasonably, then some scores will either become irrelevant or all-important. For instance, in the exaggerated example of having bit pattern A, A′, B, and B′ scored at 3, but patterns C, and C′ are scored at 50 and patterns D and D′ are scored at 55, then patterns A, A′, B, and B′ are irrelevant.

Also, in the exaggerated example of having the scoring of the patterns being the same as in FIG. 3, but change pattern D and D′ to a score of 50, then pattern D and D′ becomes all-important and all other patterns become irrelevant. Also, in this embodiment of the bit slicer system 100, the desired outcome is to find and center a bit. If the desired outcome is to find the transitions of a bit, then the scoring would be considerably different, with patterns A, A′, B, B′, C, C′, D, and D′ having a very low or no score and the patterns that are not scored in this embodiment would have higher scores. The most desired outcome will have the highest score, with other patterns close to the desired outcome having intermediate scores, any special cases are also considered in the scoring hierarchy, and any pattern with little or no significance have low or no scores.

It will be still further appreciated by those of skill in the art that the bit slicer system 100 and methods implemented thereby may be used in a myriad of applications and with a myriad of transmission media. Examples of applications and transmission media include PA systems, remote speakers (having wired or wireless connections), streaming digital audio, deep space communications, fiber optic networks, high noise communication environments, radios, walkie-talkies, and cell phones. The bit slicer system 100 may also replace any prior art bit slicer systems and may achieve a lower bit error rate (BER) than these prior art bit slicer systems, and thus improve the error rate of the overall system, which may result in a longer range of operation for an upgraded system. It will be appreciated that any asynchronous communication of data may benefit from the bit slicer system 100 and methods implemented thereby.

Throughout this specification, unless the context requires otherwise, the words “comprise” and “include” and variations such as “comprising” and “including” will be understood to imply the inclusion of an item or group of items, but not the exclusion of any other item or group items.

While various embodiments of the invention have been described, it will be apparent to those of ordinary skill in the art that many more embodiments and implementations are possible within the scope of the invention. Furthermore, although various indications have been given as to the scope of this invention, the invention is not limited to any one of these but may reside in two or more of these combined together. Accordingly, the invention is not to be restricted except in light of the attached claims and their equivalents.

1. A bit slicer system for synchronizing a data stream, comprising:
a processor, wherein the processor comprises a shift register;
a memory coupled to the processor;
an input coupled to the processor, wherein the input is configured to receive a binary data stream; and
an output coupled to the processor, wherein the output is configured to transmit a data stream that is a function of the binary data stream;
wherein the memory stores a control algorithm that instructs the processor to read a contiguous plurality of binary samples from the binary data stream, shift the contiguous plurality of binary samples through the shift register, and match a contiguous subset of the contiguous plurality of binary samples to a predetermined pattern of a plurality of predetermined patterns to determine a score.

2. The system of claim 1 wherein the control algorithm further instructs the processor to adjust the shift register based on the score.

3. The system of claim 1, wherein the processor and the memory are integrated into a single device.

4. The system of claim 3, wherein the single device is a gate array device.

5. The system of claim 3, wherein the single device is an ASIC.

6. The system of claim 1, wherein the processor is a gate array device.

7. The system of claim 1, further comprising an asynchronous data receiver coupled between the input and the processor.

8. A bit slicer system for synchronizing a data stream, comprising:
a processor, wherein the processor comprises a shift register and a bit function generator configured to generate a score for a plurality of binary samples;
an input coupled to the processor, wherein the input is configured to receive a binary data stream;
a memory coupled to the processor, wherein the memory stores a control algorithm that instructs the processor to read a contiguous plurality of binary samples from the binary data stream, shift the contiguous plurality of binary samples through the shift register, load a subset of the contiguous plurality of binary samples into the bit function generator; and
an output coupled to the processor, wherein the output is configured to transmit a data stream that is based on of the binary data stream.

9. The system of claim 8, wherein the control algorithm further instructs the processor to adjust the shift register based on the score generated by the bit function generator.

10. The system of claim 8, wherein the processor and the memory are integrated into a single device.

11. The system of claim 10, wherein the single device is a gate array device.

12. The system of claim 10, wherein the single device is an ASIC.

13. The system of claim 8, wherein the processor is a gate array device.

14. The system of claim 8, further comprising an asynchronous data receiver coupled between the input and the processor.

15. The system of claim 8, wherein the bit function generator is further configured to match the plurality of binary samples to a predetermined pattern of a plurality of predetermined patterns to generate the score for the plurality of binary samples.

16. A bit slicer system for synchronizing a data stream, comprising:
a processor, comprising:
a shift register;
a plurality of particle processors coupled to the shift register, wherein each particle processor is configured to generate a voted majority for a plurality of binary samples; and
a bit function generator coupled to the plurality of particle processors, wherein the bit function generator is configured to generate a score from the plurality of voted majorities;
an input coupled to the processor, wherein the input is configured to receive a binary data stream;
a memory coupled to the processor, wherein the memory stores a control algorithm that instructs the processor to read a contiguous plurality of binary samples from the binary data stream, shift the contiguous plurality of binary samples through the shift register, load subsets of the contiguous plurality of binary samples into the particle processors, load the plurality of voted majorities generated by the particle processors into the bit function generator; and
an output coupled to the processor, wherein the output is configured to transmit a data stream that is a based on the binary data stream.

17. The system of claim 16, wherein the control algorithm further instructs the processor to adjust the shift register based on the score generated by the bit function generator.

18. The system of claim 16, wherein the processor and the memory are integrated into a single device.

19. The system of claim 18, wherein the single device is a gate array device.

20. The system of claim 18, wherein the single device is an ASIC.

21. The system of claim 16, wherein the processor is a gate array device.

22. The system of claim 16, further comprising an asynchronous data receiver coupled between the input and the processor.

23. The system of claim 16, wherein the bit function generator is further configured to match the plurality of voted majorities to a predetermined pattern of a plurality of predetermined patterns in order to generate the score for the plurality of voted majorities.

24. A method for synchronizing a data stream, comprising the steps of:
storing a set in a memory, wherein the set contains a plurality of patterns and a plurality of scores, and each pattern has an associated score;
sampling a binary data stream periodically to generate a plurality of samples;
loading each sample into a shift register;
matching a group of the samples in the shift register to a pattern of the set;
adjusting the shift register as a function of the score associated with the matched pattern of the set.

25. The method of claim 24, wherein adjusting the shift register includes adding an additional sample to the shift register.

26. The method of claim 24, wherein adjusting the shift register includes removing a sample from the shift register.

27. The method of claim 24, wherein the binary data stream has a bit rate frequency, and sampling the binary data stream periodically includes sampling the binary data stream at a frequency higher than the bit rate frequency.

28. The method of claim 24, wherein matching a group of the samples includes matching a plurality of groups of the samples to a plurality of patterns of the set, and adjusting the shift register as a function of a sum of the scores associated with the matched plurality of the patterns of the set.

29. The method of claim 24, wherein adjusting the shift register includes storing a plurality of scores associated with matched patterns of the set, and adjusting the shift register based on the sum of the stored plurality of scores.

30. The method of claim 24, wherein adjusting the shift register includes:
generating a command based on the score associated with the matched pattern of the set;
establishing a counter for shift left and shift right commands;
shifting the shift register right when a first number of more shift right commands than shift left commands have been counted with the counter, or shifting the shift register left when a second number of more shift left commands than shift right commands have been counted with a counter; and
adjusting the counter based on the first number of the second number, respectively.

31. The method of claim 24, wherein the first and second number are equal such that shifting the shift register right or shifting the shift register left is accomplished symmetrically.

32. A method for synchronizing a data stream, comprising the steps of:
storing a set in a memory, wherein the set contains a plurality of patterns and a plurality of scores, and each pattern has an associated score;
sampling a binary data stream periodically to generate a plurality of samples;
loading each sample into a shift register;
calculating a number of binary particle values for a number of groups of samples, wherein each binary particle value is the voted majority for the respective group of samples;
matching the number of binary particle values to a pattern of the set; and
adjusting the shift register as a function of the score associated with the matched pattern of the set.

33. The method of claim 32, wherein adjusting the shift register includes adding an additional sample to the shift register.

34. The method of claim 32, wherein adjusting the shift register includes removing a sample from the shift register.

35. The method of claim 32, wherein the binary data stream has a bit rate, and sampling the binary data stream periodically includes sampling the binary data stream at a period less than the inverse of the bit rate.

36. The method of claim 32, wherein adjusting the shift register includes storing a plurality of scores associated with matched patterns of the set, and adjusting the shift register based on the sum of the stored plurality of scores.

37. The method of claim 32, wherein adjusting the shift register includes:
generating a command based on the score associated with the matched pattern of the set;
establishing a counter for shift left and shift right commands;
shifting the shift register right when a first number of more shift right commands than shift left commands have been counted with the counter, or shifting the shift register left when a second number of more shift left commands than shift right commands have been counted with the counter; and
adjusting the counter based on the first number or the second number, respectively.

38. The method of claim 37, wherein the first and second number are equal such that shifting the shift register right or shifting the shift register left is accomplished symmetrically.
